(19) United States
(12) Patent Application Publication
(10) Pub. No.: US 2022/0285816 A1
(43) Pub. Date: Sep. 8, 2022

(54) MILLIMETER WAVE 90-DEGREE 3DB COUPLERS FOR FLIP-CHIP ON-DIE IMPLEMENTATION

(71) Applicant: Mobix Labs, Inc., Irvine, CA (US)

(72) Inventors: Oleksandr Gorbachov, Irvine, CA (US); Lisette L. Zhang, Irvine, CA (US)

(21) Appl. No.: 17/653,973

(22) Filed: Mar. 8, 2022

Related U.S. Application Data
(60) Provisional application No. 63/158,110, filed on Mar. 8, 2021.

(51) Int. Cl. H01P 5/18; H01L 23/66

(52) U.S. Cl. CPC H01P 5/185; H01L 23/66; H01L 2223/6627

(57) ABSTRACT

A 90-degree 3 dB coupler with an input port, an isolated port, a first output port, and a second output port has an input connector strip connected to the input port, and an isolated port connector strip connected to the isolated port. A first output connector strip is connected to the first output port, and a second output connector strip is connected to the second output port. A first interconnect strip is connected to the input connector strip and a second interconnect strip is connected to the isolated port connector strip. A first one of conductive coupled strips extend from the input connector strip to the second output connector strip, while a second one of the conductive coupled strips extend from the first interconnect strip to the second interconnect strip. A third one of the conductive coupled strips extends from the first interconnect strip to the second output connector strip.

### CROSS-REFERENCE TO RELATED APPLICATIONS

This application relates to and claims the benefit of U.S. Provisional Application No. 63/158,110, filed Mar. 8, 2021 and entitled “MM-WAVE 90 DEGREE 3DB COUPLERS FOR FLIP-CHIP ON-DIE IMPLEMENTATION”, the disclosure of which is wholly incorporated by reference in its entirety herein.

### STATEMENT RE: FEDERALLY SPONSORED RESEARCH/DEVELOPMENT

Not Applicable

### BACKGROUND

### 1. Technical Field

The present disclosure related generally to radio frequency (RF) circuit components and couplers specifically, and more particularly to millimeter-wave 90-degree 3 dB couplers for flip-chip on-die implementation.

### 2. Related Art

Couplers are passive devices utilized to couple a part of the transmission power on one signal path to another signal path by a predetermined amount, and 3 dB 90-degree couplers in particular are widely used in RF circuits and systems. For example, quadrature power splitter/combiners in power amplifiers and low noise amplifiers utilize 3 dB 90-degree couplers, as do local oscillator (LO) or main signal distribution systems in image-reject transmitters and receivers, and so forth. In its simplest form, as its nomenclature suggests, a 3 dB 90-degree coupler operates to split an RF signal applied to one port into two output chains with half the input signal power at each, with the phase difference across the split ports is 90 degrees. The key parameters of the coupler are the amplitude balance and phase balance between the split ports, with conventional implementations typically having specifications of less than 1 dB and less than 5 degrees, respectively. Conventional couplers, however, have a fairly large footprint in semiconductor die implementations.

Multiple splitter structures may be used, while the smallest footprints may be achieved with Lange couplers, which have four ports (input port, coupled port, direct port, isolated port) and generally defined by interdigitated transmission or metal microstrip lines. The minimum dimension of the coupled strip line is equal to one quarter wavelength. The main coupling over the strip lines, which define the amplitude balance, is strongly dependent on the spacing between the metal strips. Furthermore, the surrounding area around the microstrip lines must be free of other metal structures, because otherwise, coupling and amplitude balance may be significantly changed. The high dielectric constant of semiconductor substrates such as silicon or gallium arsenide, typically greater than 10, permits a substantial reduction in the maximum footprint of the entire coupler. There has been a continuous effort in the art to decrease the footprint further, with various zig-zag or meander type configurations being one effective approach to this end. Additionally, the placement of coupled traces on different metal layers has also contributed to overall footprint reduction.

The high dielectric constant of the semiconductor substrate also assists in the reduction in footprint in configurations where the coupler is placed on the top of the substrate while the bottom of the substrate is operating as an RF ground plane. The other dimensions of the coupler are still comparatively large, which results in increased production costs of the overall semiconductor die.

In part due to the miniaturization trends in the electronics and semiconductor fields, flip-chip configurations where the semiconductor die is disposed on multiple carriers are popular. However, in a flip-chip configuration, the advantage provided by the high dielectric constant of semiconductor substrates may be diminished, as the RF ground plane is typically positioned on the die carrier with the coupler structure being placed in between. The dielectric constant of this intermediate material is understood to be substantially less than 10, and more commonly 3 to 4.

Accordingly, there is a need in the art for reducing the footprint of the coupler in flip-chip configurations. Increasing the operating bandwidth of the couplers is a high design priority for multiple applications, and while the reduction of absolute power loss is important, amplitude balance is more critical. Coupling between the metal traces is understood to be limited by specific geometries depending on fabrication technology, so it would be desirable for coupler configurations that mitigate the foregoing constraints. It would be preferable for such configurations to be implemented across a wide range of semiconductor technologies, as well as in low temperature co-fired ceramic (LTCC) and laminate structures.

### BRIEF SUMMARY

The embodiments of the present disclosure include 3 dB 90-degree couplers that utilize additional capacitive coupling via conductive strips, patches, and stubs across multiple layers. The different shapes and sizes of the capacitively coupled structures allow control of frequency dependence of amplitude and phase over a wide frequency range. The embodiments of the coupler may be implemented in different semiconductor technologies as well as in low-temperature co-fired ceramic and laminate structures.

According to one embodiment, the coupler may include an input port, an isolated port, a first output port, and a second output port. The coupler may include an input connector strip that may be connected to the input port, and an isolated port connector strip that may be connected to the isolated port. The isolated port connector strip may also be spaced apart from the input port. The coupler may further include a first output connector strip that is connected to the first output port, and a second output connector strip connected to the second output port. The second output connector strip may be spaced apart from the first output connector strip. The coupler may also include a first interconnect strip that may be connected to the input connector strip as well as a second interconnect strip that may be connected to the isolated port connector strip. There may also be a plurality of conductive coupled strips. A first one of the conductive coupled strips may extend from the input connector strip to the second output connector strip. A second one of the conductive coupled strips may extend from the first interconnect strip to the second interconnect strip. A third one of the conductive coupled strips may extend from the first interconnect strip to the second output connector strip.

Another embodiment of the present disclosure may be a coupler with an input port, an isolated port, a first output port, and a second output port. The coupler may include a middle loop strip that is connected to the input port and the first output port. There may also be an inner loop strip that is connected to the second output port and the isolated port, and spaced apart from the middle loop strip. The coupler may include an outer loop strip that is connected to the second output port and the isolated port and spaced apart from the middle loop strip. There may be a first interconnect strip that bridges a first end of the inner loop strip to a first end of the outer loop strip and connected to the second output port. The coupler may also include a second interconnect strip that bridges a second end of the inner loop strip to a second end of the outer loop strip, and connected to the isolated port. There may be one or more compensating conductive stubs, with the middle loop strip being in an at least a partially overlapping relationship with each of the one or more compensating conductive stubs.

The present disclosure will be best understood accompanying by reference to the following detailed description when read in conjunction with the drawings.

### BRIEF DESCRIPTION OF THE DRAWINGS

These and other features and advantages of the various embodiments disclosed herein will be better understood with respect to the following description and drawings, in which like numbers refer to like parts throughout, and in which:

FIG. 1A is a cross-sectional view of one exemplary flip-chip configuration;

FIG. 1B is a cross-sectional view of another exemplary flip-chip configuration;

FIG. 2A is a top plan view of an 90-degree 3 dB coupler in accordance with a first embodiment of the present disclosure;

FIG. 2B is a detailed top plan view of the coupler shown in FIG. 2A, with an expanded view of a first output port and an isolated port;

FIG. 3 is a perspective view of the coupler shown in FIG. 2A;

FIG. 4 is graph plotting the S-parameters for the simulated performance parameters of the first embodiment of the coupler;

FIG. 5 is a graph plotting the simulated phase shift performance over a frequency sweep of the first embodiment of the coupler;

FIG. 6 is a top plan view of a second embodiment of the 90-degree 3 dB coupler which includes a floating metal patch adjacent to outer ones of conductive coupled strips;

FIG. 7 is a perspective view of the second embodiment of the coupler showing the second output port and the input port;

FIG. 8 is graph plotting the S-parameters for the simulated performance parameters of the second embodiment of the coupler;

FIG. 9 is a graph plotting the simulated phase shift performance over a frequency sweep of the second embodiment of the coupler;

FIG. 10A is a top plan view of a third embodiment of the 90-degree 3 dB coupler which includes a floating metal patch adjacent to outer ones of conductive coupled strips and a compensating metal stub;

FIG. 10B is a detailed top plan view of the third embodiment of the coupler;

FIG. 11 is a perspective view of the third embodiment of the coupler;

FIG. 12 is graph plotting the S-parameters for the simulated performance parameters of the third embodiment of the coupler;

FIG. 13 is a graph plotting the simulated phase shift performance over a frequency sweep of the third embodiment of the coupler;

FIG. 14A is a top plan view of a fourth embodiment of the 90-degree 3 dB coupler which includes a set of compensation stubs along the conductive coupled strips

FIG. 14B is a detailed top plan view of the fourth embodiment of the coupler;

FIG. 15 is a perspective view of the fourth embodiment of the coupler;

FIG. 16 is graph plotting the S-parameters for the simulated performance parameters of the fourth embodiment of the coupler;

FIG. 17 is a graph plotting the simulated phase shift performance over a frequency sweep of the fourth embodiment of the coupler;

FIG. 18 is a detailed top plan view of a fifth embodiment of the 90-degree 3 dB coupler which includes an elongate compensation stub aligned with the conductive coupled strips;

FIG. 19 is a perspective view of the fifth embodiment of the coupler;

FIG. 20 is graph plotting the S-parameters for the simulated performance parameters of the fifth embodiment of the coupler;

FIG. 21 is a graph plotting the simulated phase shift performance over a frequency sweep of the fifth embodiment of the coupler;

FIG. 22 is a top plan view of a sixth embodiment of the 90-degree 3 dB coupler which includes a shorter elongate compensation stub;

FIG. 23 is a perspective view of the sixth embodiment of the coupler;

FIG. 24 is graph plotting the S-parameters for the simulated performance parameters of the sixth embodiment of the coupler;

FIG. 25 is a graph plotting the simulated phase shift performance over a frequency sweep of the sixth embodiment of the coupler;

FIG. 26 is a top plan view of a seventh embodiment of the 90-degree 3 dB coupler;

FIG. 27 is a perspective view of the seventh embodiment of the coupler;

FIG. 28 is graph plotting the S-parameters for the simulated performance parameters of the seventh embodiment of the coupler;

FIG. 29 is a graph plotting the simulated phase shift performance over a frequency sweep of the seventh embodiment of the coupler;

FIG. 30 is a top plan view of an eighth embodiment of the 90-degree 3 dB coupler;

FIG. 31A is a perspective view of the eight embodiment of the coupler;

FIG. 31B is a detailed perspective view of the eight embodiment of the coupler showing an underside thereof;

FIG. 32 is graph plotting the S-parameters for the simulated performance parameters of the eighth embodiment of the coupler; and

FIG. 33 is a graph plotting the simulated phase shift performance over a frequency sweep of the eighth embodiment of the coupler.

### DETAILED DESCRIPTION

The present disclosure encompasses various embodiments of a 3 dB 90-degree coupler that avoids conventional design constraints with the use of an additional, different type of capacitive coupling using conductive strips, patches, and stubs on different layer. It is contemplated that adjusting the size and shape of the capacitively coupled metal structures will permit the control of frequency dependence on amplitude and phase of coupled ports over a wide frequency range.

The detailed description set forth below in connection with the appended drawings is intended as a description of the several presently contemplated embodiments of the 3 dB 90-degree coupler and is not intended to represent the only form in which the disclosed invention may be developed or utilized. The description sets forth the functions and features in connection with the illustrated embodiments. It is to be understood, however, that the same or equivalent functions may be accomplished by different embodiments that are also intended to be encompassed within the scope of the present disclosure. It is further understood that the use of relational terms such as first and second and the like are used solely to distinguish one from another entity without necessarily requiring or implying any actual such relationship or order between such entities.

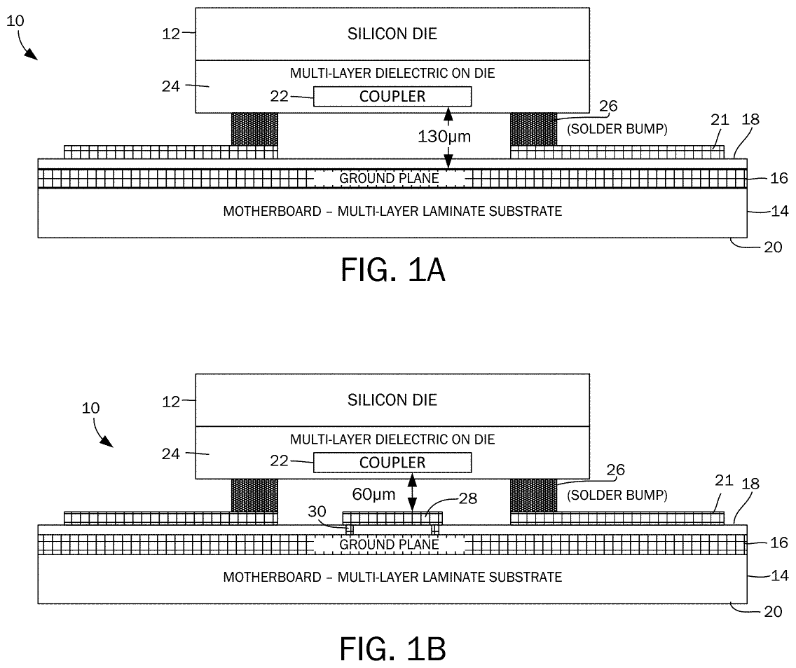

With reference to FIG. 1A, one implementation of a flip-chip configuration 10 is shown, which generally includes a semiconductor die 12 that is mounted on to a motherboard 14 or other multi-layer laminate substrate. In further detail, the motherboard 14 includes a ground plane 16 embedded therein and unexposed on a top surface 18 or a bottom surface 20 of the motherboard 14. The top surface 18 of the motherboard 14 includes conductive traces 21 that are a part of the circuit interconnecting the semiconductor die 12 to other components. According to various embodiments of the present disclosure, a coupler 22 is incorporated into the semiconductor die 12 and may be embedded within a multi-layer dielectric 24. The semiconductor die 12, in turn, is mounted on to the motherboard 14 with solder bumps 26. In this configuration, the spacing between the coupler 22 and the ground plane 16 may be 130 μm.

FIG. 1B illustrated another implementation of a flip-chip configuration 10. Similar to the first implementation discussed above, the semiconductor die 12 includes the multi-layer dielectric 24 within which the coupler 22 is embedded. The semiconductor die 12 is attached to the conductive traces on the motherboard 14 with the solder bumps 26. This motherboard 14 likewise includes the ground plane 16 but includes an exposed ground plane 28 on the top surface 18. The exposed ground plane 28 is electrically contiguous with the ground plane 16 by way of vias 30. In this configuration, the spacing between the coupler 22 and the exposed ground plane 28 may be 60 μm.

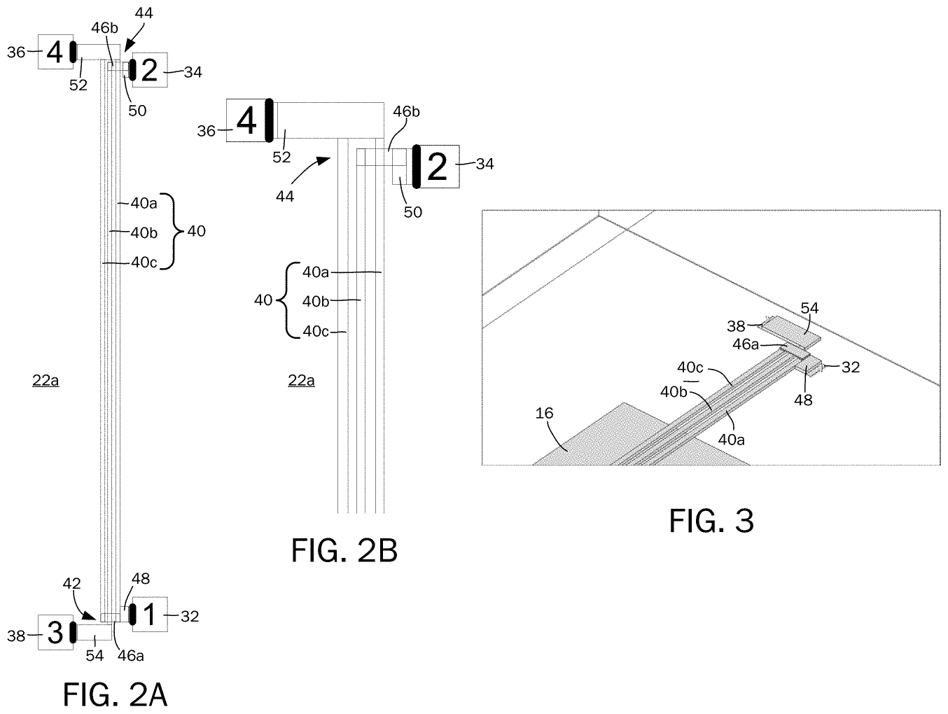

Referring now to FIGS. 2A, 2B, and 3, a first embodiment of a 90-degree 3 dB coupler 22a has an input port 32, an isolated port 34, a first output port 36, and a second output port 38. The input port 32 is understood to be connected to a signal source, and the coupler 22a splits such signal and outputs a signal attenuated by 3 dB at both the first output port 36 and the second output port 38. The phase of the signal at the first output port 36 is understood to be shifted by approximately 0 degrees, while the phase of the signal at the second output port 38 is understood to be shifted by approximately 90 degrees.

The coupler 22a is generally defined by a plurality of conductive coupled strips 40, of which there are three in this embodiment. In particular, there is a first conductive coupled strip 40a, a second conductive coupled strip 40b spaced apart from the first conductive coupled strip 40a, and a third conductive coupled strip 40c spaced apart from the second conductive coupled strip 40b. All three of the conductive coupled strips 40 are understood to extend in a parallel relationship to each other and is characterized by a first end 42 and an opposed second end 44. The length of the conductive coupled strips 40 may be approximately 750 μm. Each of the conductive coupled strips have a width of approximately 5 μm, which is understood to encompass dimensions that are within normal manufacturing tolerances above and below such value. The spacing between each of the conductive coupled strips 40 is understood to be approximately 5 μm. These dimensions, as well as all of the other dimensions of various features referenced herein, are understood to be by way of example only and not of limitation. Those having ordinary skill in the art will recognize that any other suitable set(s) of dimension(s) may be substituted. Various features of the embodiments of the present disclosure make reference to dielectric and metal layers, as well as dimensions thereof. These particulars are presented in the context of a 28 nm CMOS semiconductor process, but it will be appreciated that other processes may be substituted, with modifications to the dimensions and other specific parameters being within the purview of those having ordinary skill in the art.

The coupler 22a also includes two interconnect strips 46—a first interconnect strip 46a that is connected to the first conductive coupled strip 40a and the third conductive coupled strip 40c at the first end 42 thereof, and a second interconnect strip 46b that is connected to the second conductive coupled strip 40b at the second end 44 thereof. The first interconnect strip 46a is also connected to the input port 32 over an input connector strip 48, while the second interconnect strip 46b is connected to the isolated port 34 over an isolated port connector strip 50. The second end 44 of the first conductive coupled strip 40a and the third conductive coupled strip 40c are connected to the first output port 36 over a first output connector strip 52. The first end 42 of the second conductive coupled strip 40b, on the other hand, is connected to the second output port 38 over a second output connector strip 54.

In one exemplary embodiment, the first output connector strip 52 and the second output connector strip 54 may be implemented as an AP layer in a semiconductor die. By way of example, the thickness of such layer may be approximately 3 μm. The first interconnect strip 46a and the second interconnect strip 46b may be implemented on the M7 layer and have a thickness of approximately 1 μm. The first embodiment of the coupler 22a may be separated from the motherboard ground plane by 60 μm and have a total footprint of approximately 800×70 μm. The embodiments of the present disclosure may also describe the semiconductor layers as first metal layer, second metal layer, third metal layer, and so forth, but it is to be understood that a strict conformity between the numerically enumerated metal layers correspond to any of the conventional references to semiconductor metal layers such as the AP layer, M6 layer, or the M7 layer. In other words, in some contexts, the first metal layer may be the AP layer and the second metal layer may be the M7 layer, while in some other contexts, the first metal layer may be the M7 layer, and the second metal layer may be the M6 layer, with a third metal layer being the AP layer.

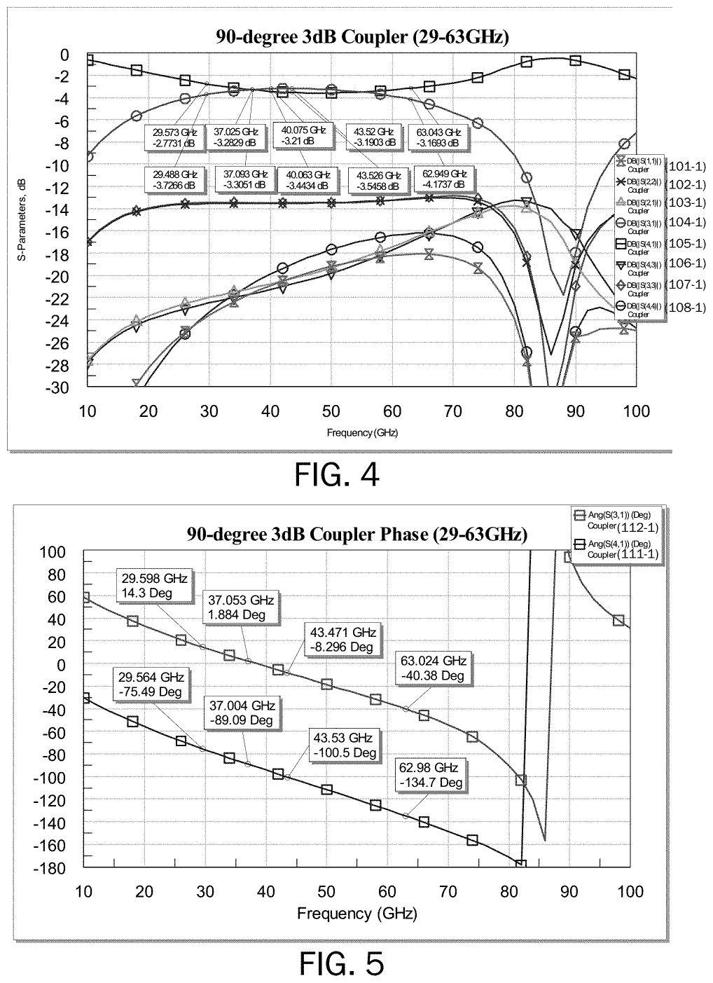

Referring now to the graph of FIGS. 4 and 5, the simulated performance of the first embodiment of the coupler 22a will be considered. FIG. 4 in particular plots the simulated scattering parameters (S-Parameters) over a frequency sweep between 10 and 100 GHz (29 to 63 GHz frequency band is defined where amplitude imbalance between output ports is below 1 dB) A first plot 101-1 shows the reflection coefficient/return loss S11 at the input port 32, and a second plot 102-1 shows the reflection coefficient S22 at the isolated port 34. A third plot 103-1 shows the insertion loss S21 between the isolated port 34 and the input port 32, and a fourth plot 104-1 the shows the insertion loss S31 between the second output port 38 and the input port 32. Similarly, a fifth plot 105-1 shows the insertion loss S41 between the first output port 36 and the input port 32. A sixth plot 106-1 shows the isolation between the first output port 36 and the second output port 38 (S43). A seventh plot 107-1 shows the output reflection coefficient S33 of the second output port 38, and an eighth plot 108-1 shows the output reflection coefficient S44 of the first output port 36.

The graph of FIG. 5 illustrates the simulated phase shift performance of the first embodiment of the coupler 22a over the same frequency sweep of 10 to 100 GHz. A first plot 111-1 shows the phase shift that gets applied to the input signal on the input port 32 when output to the first output port 36, and a second plot 112-1 shows the phase shift at the second output port 38.

The following table 1 summarizes the simulated difference in output signal power from the first output port 36 and the second output port 38, as well as the output signal phase from the same, across selected operating frequencies. Furthermore, the average power loss at either of the output ports 36, 38 for each of the selected operating frequencies are presented.

TABLE 1

| | F (GHz) | | | | |
|---|---|---|---|---|---|
| | 29.5 | 37 | 40 | 43.5 | 63 |
| | GHz | GHz | GHz | GHz | GHz |
| Delta OUT, dB | 0.95 | 0.02 | 0.23 | 0.35 | 1.0 |
| Delta Angle, | 89.79 | 90.99 | | 92.2 | 94.32 |
| degree | | | | | |
| Average Loss, | 3.25 | 3.29 | 3.33 | 3.37 | 3.67 |
| dB | | | | | |

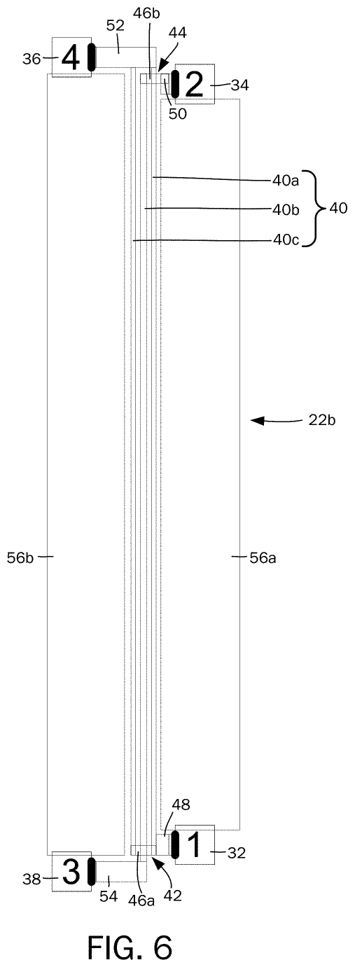

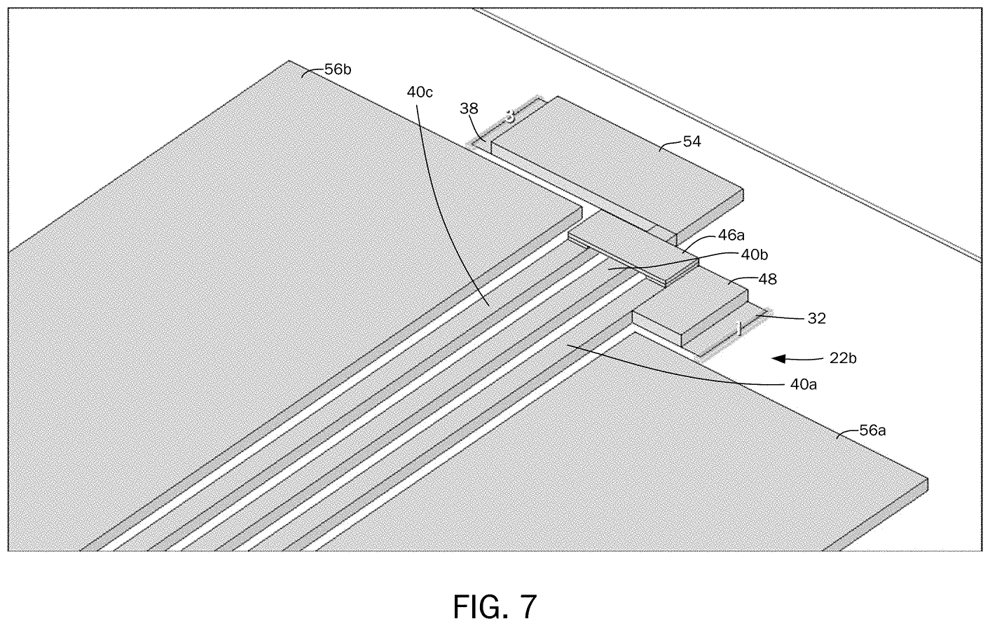

Referring now to FIGS. 6 and 7, a second embodiment of a 90-degree 3 dB coupler 22b has the input port 32, the isolated port 34, the first output port 36, and the second output port 38. The input port 32 is understood to be connected to a signal source, and like the first embodiment of the coupler 22a discussed above, this second embodiment of the coupler 22b splits such signal and outputs a signal attenuated by 3 dB at both the first output port 36 and the second output port 38. The phase of the signal at the first output port 36 may be shifted by approximately 0 degrees, while the phase of the signal at the second output port 38 is understood to be shifted by approximately 90 degrees.

The coupler 22b is again generally defined by the plurality of conductive coupled strips 40, of which there are three in this embodiment. Specifically, there is the first conductive coupled strip 40a, the second conductive coupled strip 40b spaced apart from the first conductive coupled strip 40a, and the third conductive coupled strip 40c spaced apart from the second conductive coupled strip 40b. All three of the conductive coupled strips 40 are understood to extend in a parallel relationship to each other and is characterized by the first end 42 and the opposed second end 44. The length of the conductive coupled strips 40 may be approximately 750 μm. Each of the conductive coupled strips have a width of approximately 5 μm. The spacing between each of the conductive coupled strips 40 is understood to be approximately 5 μm.

The coupler 22b also includes two interconnect strips 46, including the first interconnect strip 46a that is connected to the first conductive coupled strip 40a and the third conductive coupled strip 40c at the first end 42 thereof, and the second interconnect strip 46b that is connected to the second conductive coupled strip 40b at the second end 44 thereof. The first interconnect strip 46a is also connected to the input port 32 over the input connector strip 48, while the second interconnect strip 46b is connected to the isolated port 34 over the isolated port connector strip 50. The second end 44 of the first conductive coupled strip 40a and the third conductive coupled strip 40c are connected to the first output port 36 over the first output connector strip 52. The first end 42 of the second conductive coupled strip 40b is connected to the second output port 38 over a second output connector strip 54.

In one exemplary embodiment, the first output connector strip 52 and the second output connector strip 54 may be implemented as an AP layer in a semiconductor die, the thickness of which may be approximately 3 μm. The second embodiment of the coupler 22a further incorporates a pair of floating conductive patches 56a, 56b that are each spaced apart from the first and third conductive coupled strips 40a, 40c, respectively, by a prescribed distance. In one exemplary embodiment, this spacing may be 5 μm, and the width of the floating conductive patches 56 may be 75 μm, though again, these dimensions are exemplary only. The first floating conductive patch 56a extends generally from the input port 32 to the isolated port 34, while the second floating conductive patch 56b extends from the second output port 38 to the first output port 36. The floating conductive patches 56 may be implemented on the AP metal layer of a semiconductor die. The first interconnect strip 46a and the second interconnect strip 46b may be implemented on the M7 layer and have a thickness of approximately 1 μm. The second embodiment of the coupler 22a may be separated from the motherboard ground plane by 60 μm and have a total footprint of approximately 800×70 μm.

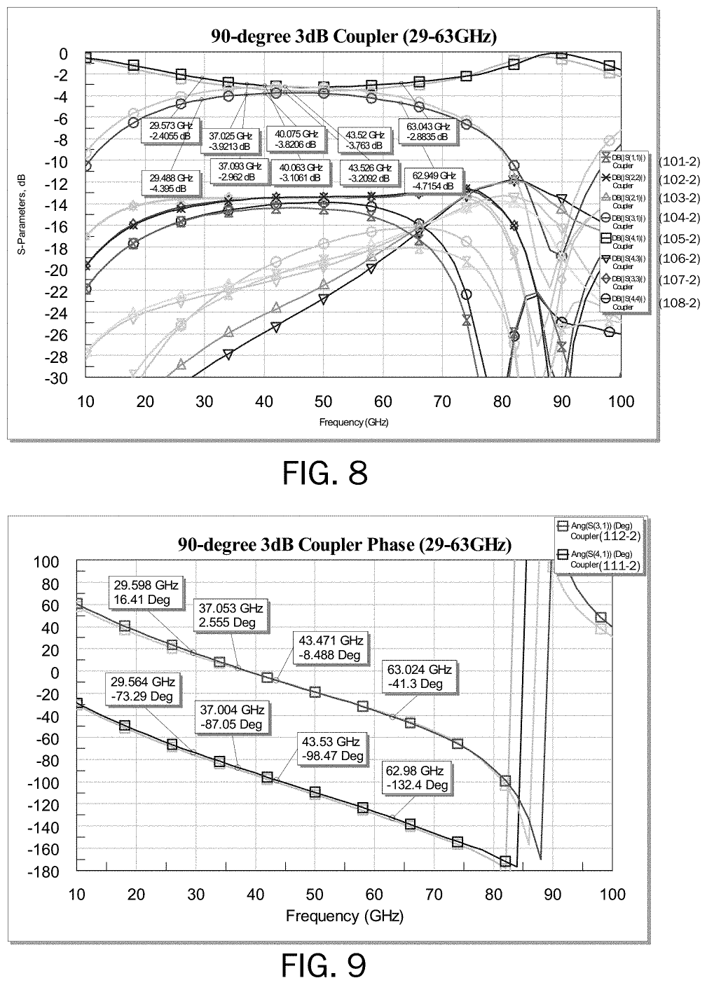

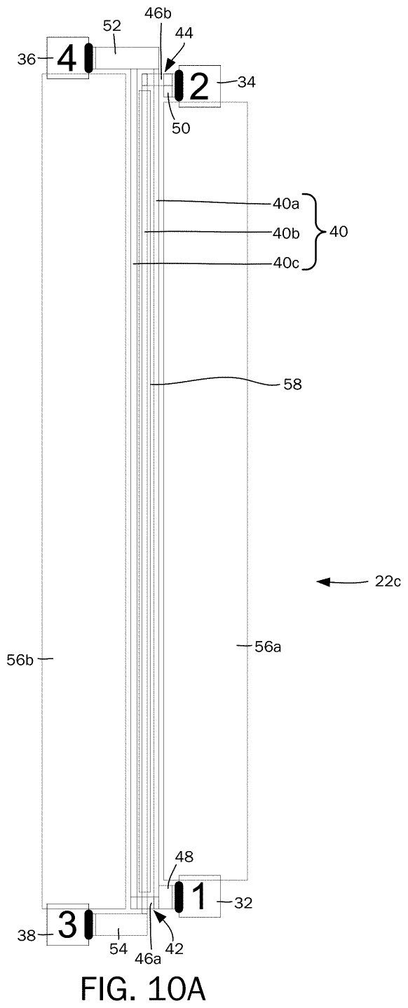

Referring now to the graph of FIGS. 8 and 9, the simulated performance of the second embodiment of the coupler 22b will be considered. FIG. 8 in particular plots the simulated scattering parameters (S-Parameters over a frequency sweep between 10 to 100 GHz, with a first plot 101-2 showing the reflection coefficient/return loss S11 at the input port 32, and a second plot 102-2 showing the reflection coefficient S22 at the isolated port 34. A third plot 103-2 shows the insertion loss S21 between the isolated port 34 and the input port 32, and a fourth plot 104-2 the shows the insertion loss S31 between the second output port 38 and the input port 32. Similarly, a fifth plot 105-2 shows the insertion loss S41 between the first output port 36 and the input port 32. A sixth plot 106-2 shows the isolation between the first output port 36 and the second output port 38 (S43). A seventh plot 107-2 shows the output reflection coefficient S33 of the second output port 38, and an eighth plot 108-2 shows the output reflection coefficient S44 of the first output port 36.

The graph of FIG. 9 illustrates the simulated phase shift performance of the second embodiment of the coupler 22b over the same frequency sweep of 10 to 100 GHz. A first plot 111-2 shows the phase shift that gets applied to the input signal on the input port 32 when output to the first output port 36, and a second plot 112-2 shows the phase shift at the second output port 38.

The following table 2 summarizes the simulated difference in output signal power from the first output port 36 and the second output port 38, as well as the output signal phase from the same, across selected operating frequencies. Furthermore, the average power loss at either of the output ports 36, 38 for each of the selected operating frequencies are presented. The second embodiment of the coupler 22b is understood to have the same dimensions as the first embodiment of the coupler 22a. The Second embodiment of the coupler 22b additionally incorporates capacitive floating patches around the coupled strip lines 40. As shown in table 2, there is understood to be higher amplitude imbalance at the edges of the frequency band compared to the first embodiment of the coupler 22a as discussed above with reference to table 1. However, phase imbalance for the second embodiment of the coupler 22b is appears to be smaller in comparison to the first embodiment of the coupler 22a.

TABLE 2

| | F (GHz) | | | | |
|---|---|---|---|---|---|
| | 29.5 | 37 | 40 | 43.5 | 63 |
| | GHz | GHz | GHz | GHz | GHz |
| Delta OUT, dB | 1.99 | 0.96 | 0.71 | 0.55 | 1.83 |
| Delta Angle, | 89.7 | 89.6 | | 89.98 | 91.1 |
| degree | | | | | |
| Average Loss, | 3.4 | 3.44 | 3.46 | 3.49 | 3.8 |
| dB | | | | | |

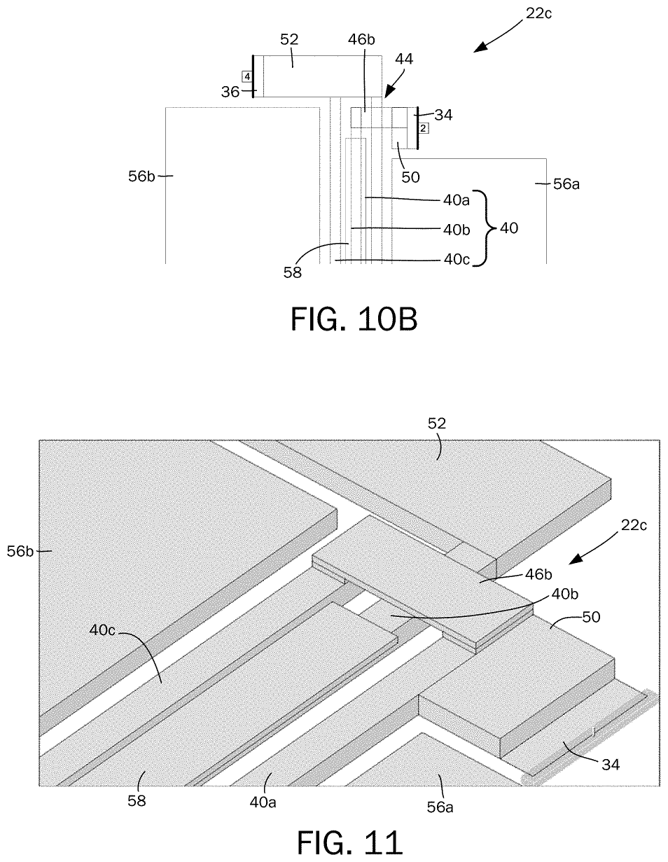

FIGS. 10A, 10B, and 11 illustrate a third embodiment of a 90-degree 3 dB coupler 22c, which likewise includes the input port 32, the isolated port 34, the first output port 36, and the second output port 38. The input port 32 is understood to be connected to a signal source, and like the first embodiment of the coupler 22a and the second embodiment of the coupler 22b discussed above, this third embodiment of the coupler 22c splits such signal and outputs a signal attenuated by 3 dB at both the first output port 36 and the second output port 38. The phase of the signal at the first output port 36 may be shifted by approximately 0 degrees, while the phase of the signal at the second output port 38 is understood to be shifted by approximately 90 degrees.

The coupler 22c is again generally defined by the plurality of conductive coupled strips 40, of which there are three, including the first conductive coupled strip 40a, the second conductive coupled strip 40b that is spaced apart from the first conductive coupled strip 40a, and the third conductive coupled strip 40c that is spaced apart from the second conductive coupled strip 40b. All three of the conductive coupled strips 40 are understood to extend in a parallel relationship to each other and is characterized by the first end 42 and the opposed second end 44. The length of the conductive coupled strips 40 may be approximately 750 μm. Each of the conductive coupled strips have a width of approximately 5 μm. The spacing between each of the conductive coupled strips 40 is understood to be approximately 5 μm.

The coupler 22c also includes two interconnect strips 46, including the first interconnect strip 46a that is connected to the first conductive coupled strip 40a and the third conductive coupled strip 40c at the first end 42 thereof, and the second interconnect strip 46b that is connected to the second conductive coupled strip 40b at the second end 44 thereof. The first interconnect strip 46a is also connected to the input port 32 over the input connector strip 48, while the second interconnect strip 46b is connected to the isolated port 34 over the isolated port connector strip 50. The second end 44 of the first conductive coupled strip 40a and the third conductive coupled strip 40c are connected to the first output port 36 over the first output connector strip 52. The first end 42 of the second conductive coupled strip 40b is connected to the second output port 38 over a second output connector strip 54.

In one exemplary embodiment, the first output connector strip 52 and the second output connector strip 54 may be implemented on an M7 layer in a semiconductor die, the thickness of which may be approximately 3 μm. The coupler 22c may be separated from the motherboard ground plane by 60 μm and have a total footprint of approximately 800×70 μm.

The third embodiment of the coupler 22c similarly incorporates the pair of floating conductive patches 56a, 56b that are in the second embodiment of the coupler 22b, and are each spaced apart from the first and third conductive coupled strips 40a, 40c, respectively, by a prescribed distance. In one exemplary embodiment, this spacing may be 5 μm, and the width of the floating conductive patches 56 may be 75 μm, though again, these dimensions are exemplary only. The first floating conductive patch 56a extends generally from the input port 32 to the isolated port 34, while the second floating conductive patch 56b extends from the second output port 38 to the first output port 36. The floating conductive patches 56 may be implemented on the M7 metal layer of a semiconductor die. The first interconnect strip 46a and the second interconnect strip 46b may be implemented on the M6 layer and have a thickness of approximately 1 μm.

The third embodiment of the coupler 22c may further include a compensating conductive stub 58 that at least partially overlaps the second conductive coupled strip 40b. The compensating conductive stub 58 extends in a parallel relationship with the second conductive coupled strip 40b, and substantially the length of the same. As described above, the conductive coupled strips 40 may have a length of approximately 750 μm, and in the illustrated embodiment, the compensating conductive stub 58 may have a length of approximately 720 μm. The width of the compensating conductive stub 58 may be approximately 10 μm, so the overlap does not encompass the first and third conductive coupled strips 40a, 40c, which are spaced 5 μm apart from the second conductive coupled strip 40b. The compensating conductive stub 58 may be implemented on the M6 layer of the semiconductor die.

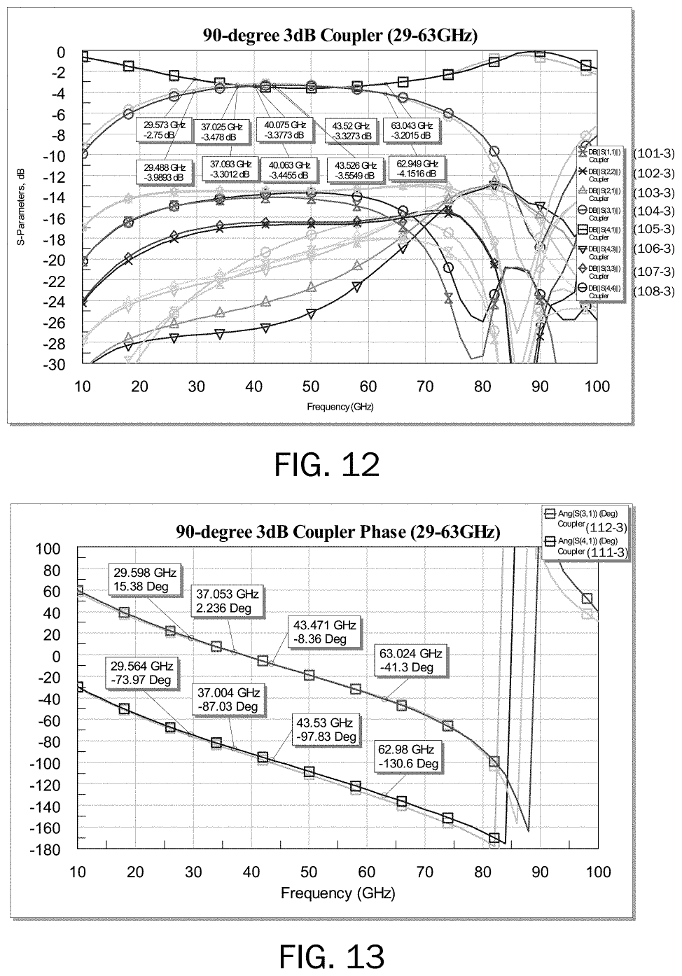

Referring now to the graphs of FIGS. 12 and 13, the simulated performance of the third embodiment of the coupler 22c will be considered. FIG. 12 in particular plots the simulated scattering parameters (S-Parameters over a frequency sweep between 10 to 100 GHz, with a first plot 101-3 showing the reflection coefficient/return loss S11 at the input port 32, and a second plot 102-3 showing the reflection coefficient S22 at the isolated port 34. A third plot 103-3 shows the insertion loss S21 between the isolated port 34 and the input port 32, and a fourth plot 104-3 the shows the insertion loss S31 between the second output port 38 and the input port 32. A fifth plot 105-3 shows the insertion loss S41 between the first output port 36 and the input port 32. A sixth plot 106-3 shows the isolation between the first output port 36 and the second output port 38 (S43). A seventh plot 107-3 shows the output reflection coefficient S33 of the second output port 38, and an eighth plot 108-3 shows the output reflection coefficient S44 of the first output port 36.

The graph of FIG. 13 illustrates the simulated phase shift performance of the third embodiment of the coupler 22c over the same frequency sweep of 10 to 100 GHz. A first plot 111-3 shows the phase shift that gets applied to the input signal on the input port 32 when output to the first output port 36, and a second plot 112-3 shows the phase shift at the second output port 38.

The following table 3 summarizes the simulated difference in output signal power from the first output port 36 and the second output port 38, as well as the output signal phase from the same, across selected operating frequencies. Furthermore, the average power loss at either of the output ports 36, 38 for each of the selected operating frequencies are presented. The third embodiment of the coupler 22c is understood to have the same dimensions as those of the second embodiment of the coupler 22b, though with the inclusion of the longitudinal capacitive stub. 58. It is understood that the addition of this stub results in decreased amplitude imbalance.

TABLE 3

| | F (GHz) | | | | |
|---|---|---|---|---|---|
| | 29.5 | 37 | 40 | 43.5 | 63 |
| | GHz | GHz | GHz | GHz | GHz |
| Delta OUT, dB | 1.24 | 0.18 | 0.07 | 0.23 | 0.95 |
| Delta Angle, | 89.35 | 89.23 | | 89.47 | 89.3 |
| degree | | | | | |
| Average Loss, | 3.37 | 3.39 | 3.41 | 3.44 | 3.68 |
| dB | | | | | |

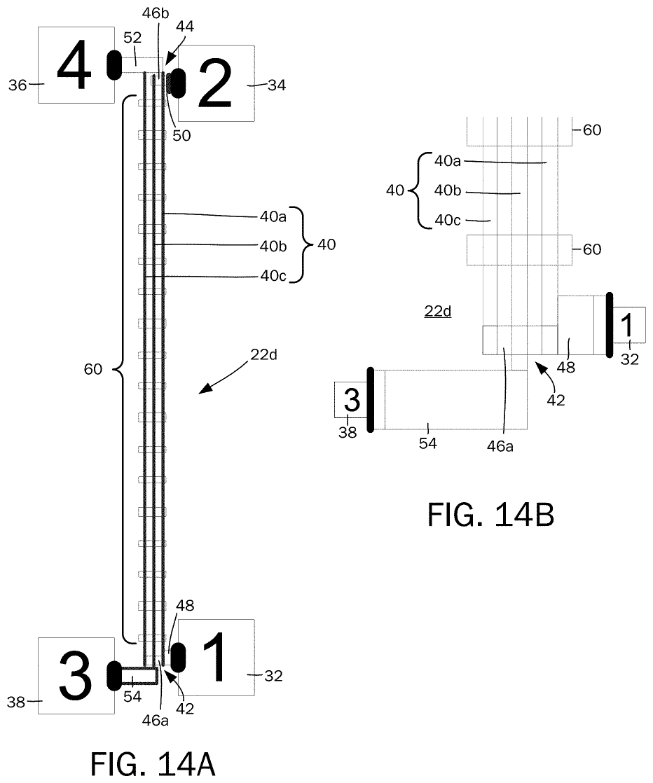

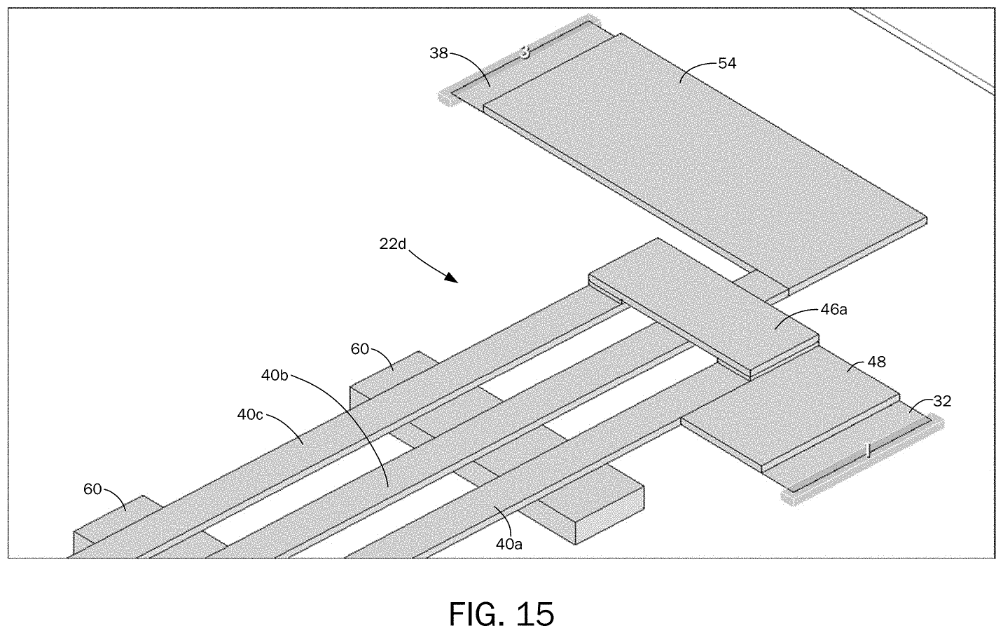

FIGS. 14A, 14B, and 15 are of a fourth embodiment of a 90-degree 3 dB coupler 22d. Again, the coupler 22 includes the input port 32, the isolated port 34, the first output port 36, and the second output port 38. The input port 32 is understood to be connected to a signal source, and like the other embodiments discussed above, this fourth embodiment of the coupler 22d splits such signal and outputs a signal attenuated by 3 dB at both the first output port 36 and the second output port 38. The phase of the signal at the first output port 36 may be shifted by approximately 0 degrees, while the phase of the signal at the second output port 38 is understood to be shifted by approximately 90 degrees.

The coupler 22d is generally defined by the plurality of conductive coupled strips 40, including the first conductive coupled strip 40a, the second conductive coupled strip 40b that is spaced apart from the first conductive coupled strip 40a, and the third conductive coupled strip 40c that is spaced apart from the second conductive coupled strip 40b. All three of the conductive coupled strips 40 are understood to extend in a parallel relationship to each other and is characterized by the first end 42 and the opposed second end 44. The length of the conductive coupled strips 40 may be approximately 750 μm. Each of the conductive coupled strips have a width of approximately 5 μm. The spacing between each of the conductive coupled strips 40 is understood to be approximately 5 μm.

The coupler 22d includes two interconnect strips 46, including the first interconnect strip 46a that is connected to the first conductive coupled strip 40a and the third conductive coupled strip 40c at the first end 42 thereof, and the second interconnect strip 46b that is connected to the second conductive coupled strip 40b at the second end 44 thereof. The first interconnect strip 46a is also connected to the input port 32 over the input connector strip 48, while the second interconnect strip 46b is connected to the isolated port 34 over the isolated port connector strip 50. The second end 44 of the first conductive coupled strip 40a and the third conductive coupled strip 40c are connected to the first output port 36 over the first output connector strip 52. The first end 42 of the second conductive coupled strip 40b is connected to the second output port 38 over a second output connector strip 54.

The first output connector strip 52 and the second output connector strip 54 may be implemented on an M7 layer in a semiconductor die, the thickness of which may be approximately 3 μm. Furthermore, the first interconnect strip 46a and the second interconnect strip 46b may be implemented on the M6 layer and have a thickness of approximately 1 μm. The coupler 22d may be separated from the motherboard ground plane by 60 μm and have a total footprint of approximately 800×70 μm.

The fourth embodiment of the coupler 22d may further include a set of compensating conductive stubs 60 that are spaced along the length of the conductive coupled strips. 40. These compensating conductive stubs 60, unlike the single compensating conductive stub 58 utilized in the third embodiment of the coupler 22, are shorter and are oriented crosswise to the conductive coupled strips 40. The compensating conductive stubs also extend the entire width of the first, second and third conductive coupled strips 40, and beyond. By way of example, the compensating conductive stubs 60 may have a width of 10 μm, and may be located on the AP layer of the semiconductor die 12.

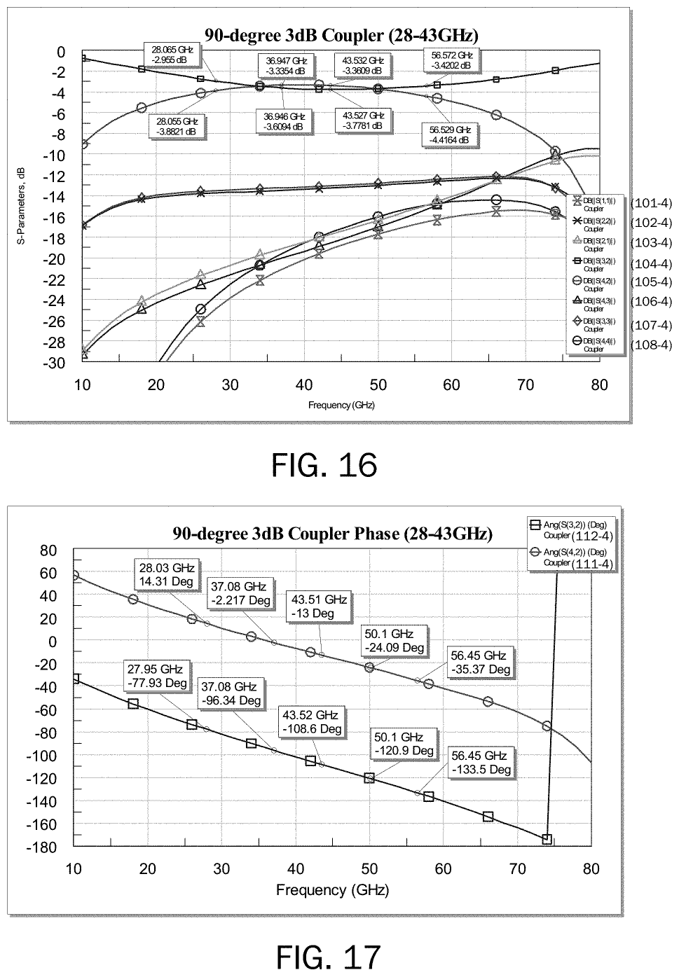

Referring now to the graphs of FIGS. 16 and 17, the simulated performance of the fourth embodiment of the coupler 22d will be considered. FIG. 16 in particular plots the simulated scattering parameters (S-Parameters over a frequency sweep between 10 to 80 GHz, with a first plot 101-4 showing the reflection coefficient/return loss S11 at the input port 32, and a second plot 102-4 showing the reflection coefficient S22 at the isolated port 34. A third plot 103-4 shows the insertion loss S21 between the isolated port 34 and the input port 32, and a fourth plot 104-4 the shows the insertion loss S31 between the second output port 38 and the input port 32. A fifth plot 105-4 shows the insertion loss S41 between the first output port 36 and the input port 32. A sixth plot 106-3 shows the isolation between the first output port 36 and the second output port 38 (S43). A seventh plot 107-4 shows the output reflection coefficient S33 of the second output port 38, and an eighth plot 108-4 shows the output reflection coefficient S44 of the first output port 36.

The graph of FIG. 17 illustrates the simulated phase shift performance of the fourth embodiment of the coupler 22d over the same frequency sweep of 10 to 80 GHz (a 27 to 57 GHz referenced frequency range in which amplitude imbalance is below 1 dB). A first plot 111-4 shows the phase shift that gets applied to the input signal on the input port 32 when output to the first output port 36, and a second plot 112-4 shows the phase shift at the second output port 38.

The following table 4 summarizes the simulated difference in output signal power from the first output port 36 and the second output port 38, as well as the output signal phase from the same, across selected operating frequencies. Furthermore, the average power loss at either of the output ports 36, 38 for each of the selected operating frequencies are presented.

TABLE 4

| | F (GHz) | | | | |
|---|---|---|---|---|---|
| | 28 | 37 | 43.5 | 50 | 56.5 |
| | GHz | GHz | GHz | GHz | GHz |
| Delta OUT, dB | 0.93 | 0.27 | 0.42 | | 1.0 |
| Delta Angle, | 92.24 | 94.12 | 95.6 | 96.81 | 98.13 |
| degree | | | | | |
| Average Loss, | 3.42 | 3.47 | 3.57 | | 3.93 |
| dB | | | | | |

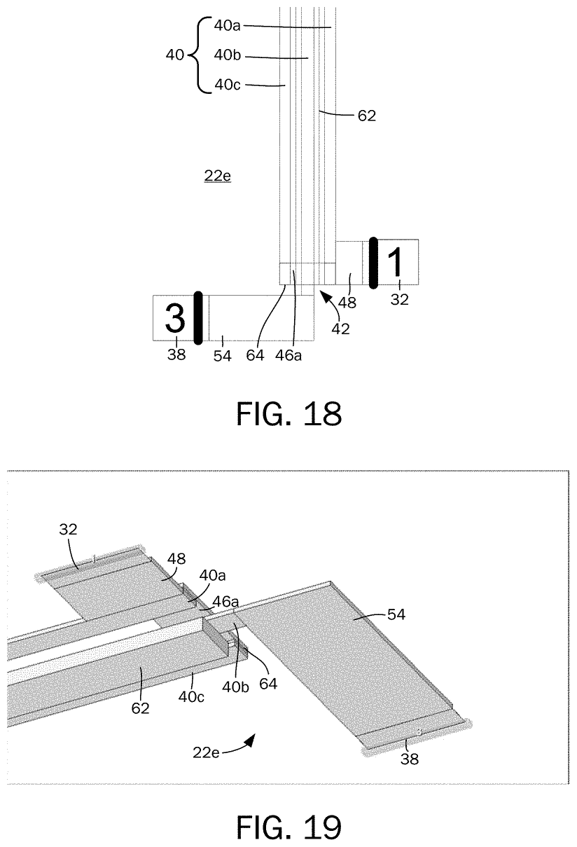

FIGS. 18 and 19 depict a fifth embodiment of a 90-degree 3 dB coupler 22e, which includes the input port 32, the isolated port (not shown), the first output port (not shown), and the second output port 38. The input port 32 is understood to be connected to a signal source, and like the other embodiments discussed above, this fifth embodiment of the coupler 22e splits such signal and outputs a signal attenuated by 3 dB at both the first output port and the second output port 38. The phase of the signal at the first output port may be shifted by approximately 0 degrees, while the phase of the signal at the second output port 38 is understood to be shifted by approximately 90 degrees.

The foundational components of the fifth embodiment of the coupler 22e are understood to be the same as those of the fourth embodiment 22d. That is, the coupler 22e is generally defined by the plurality of conductive coupled strips 40, including the first conductive coupled strip 40a, the second conductive coupled strip 40b that is spaced apart from the first conductive coupled strip 40a, and the third conductive coupled strip 40c that is spaced apart from the second conductive coupled strip 40b. All three of the conductive coupled strips 40 are understood to extend in a parallel relationship to each other.

The coupler 22e includes two interconnect strips 46, including the first interconnect strip 46a that is connected to the first conductive coupled strip 40a and the third conductive coupled strip 40c, and the second interconnect strip (not shown) that is connected to the second conductive coupled strip 40b. The first interconnect strip 46a is also connected to the input port 32 over the input connector strip 48. The second output connector strip 54 is connected to the second output port 38, as well as the second conductive coupled strip 40b.

The first output connector strip (not shown) and the second output connector strip 54 may be implemented on an M7 layer in the semiconductor die, the thickness of which may be approximately 3 μm. Furthermore, the first interconnect strip 46a and the second interconnect strip 46b (not shown) may be implemented on the M6 layer and have a thickness of approximately 1 μm. The coupler 22e may be separated from the motherboard ground plane by 60 μm and have a total footprint of approximately 800×70 μm.

The fifth embodiment of the coupler 22e may incorporate a longitudinal compensating conductive stub 62 that extend the length of the conductive coupled strips 40. In further detail, the longitudinal compensating conductive stub 62 may overlap the second conductive coupled strip 40b to the extent of an outer edge 64 of the first interconnect strip 46a. On the opposite end, the longitudinal compensating conductive stub 62 may extend to an outer edge of the second interconnect strip (not shown). In this regard, the second conductive coupled strip 40b may define an extension region 66 that does not overlap with the longitudinal compensating conductive stub 62, and the first and third conductive coupled strips 40a, 40c may likewise have a like extension region. The width of the longitudinal compensating conductive stub 62 may be 10 μm, and located on the AP layer of the semiconductor die 12.

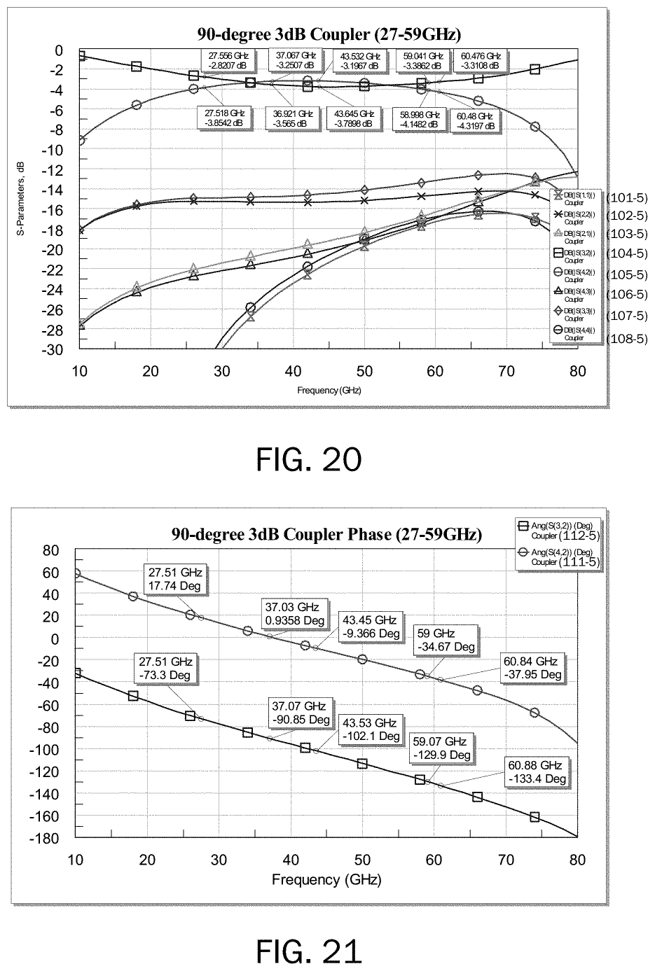

The graphs of FIGS. 20 and 21 show the simulated performance of the fifth embodiment of the coupler 22e. FIG. 16 plots the simulated scattering parameters (S-Parameters over a frequency sweep between 10 to 80 GHz, with a first plot 101-5 showing the reflection coefficient/return loss S11 at the input port 32, and a second plot 102-5 showing the reflection coefficient S22 at the isolated port 34. A third plot 103-5 shows the insertion loss S21 between the isolated port 34 and the input port 32, and a fourth plot 104-5 the shows the insertion loss S31 between the second output port 38 and the input port 32. A fifth plot 105-5 shows the insertion loss S41 between the first output port 36 and the input port 32. A sixth plot 106-5 shows the isolation between the first output port 36 and the second output port 38 (S43). A seventh plot 107-5 shows the output reflection coefficient S33 of the second output port 38, and an eighth plot 108-5 shows the output reflection coefficient S44 of the first output port 36.

The graph of FIG. 21 illustrates the simulated phase shift performance of the fifth embodiment of the coupler 22e over the same frequency sweep of 10 to 80 GHz. A first plot 111-5 shows the phase shift that gets applied to the input signal on the input port 32 when output to the first output port 36, and a second plot 112-5 shows the phase shift at the second output port 38.

The following table 5 summarizes the simulated difference in output signal power from the first output port 36 and the second output port 38, as well as the output signal phase from the same, across selected operating frequencies. The average power loss at either of the output ports 36, 38 for each of the selected operating frequencies are also presented.

TABLE 5

| | F (GHz) | | | | |
|---|---|---|---|---|---|
| | 27.5 | 37 | 43.5 | 50 | 56.5 |
| | GHz | GHz | GHz | GHz | GHz |
| Delta OUT, dB | 1.0 | 0.31 | 0.59 | 0.76 | 1.0 |
| Delta Angle, | 91.04 | 91.78 | 92.73 | 95 | 95.45 |
| degree | | | | | |
| Average Loss, | 3.34 | 3.41 | 3.49 | 3.77 | 3.82 |
| dB | | | | | |

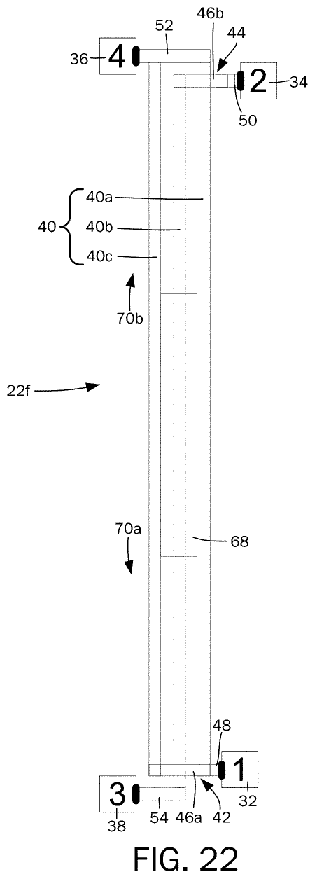

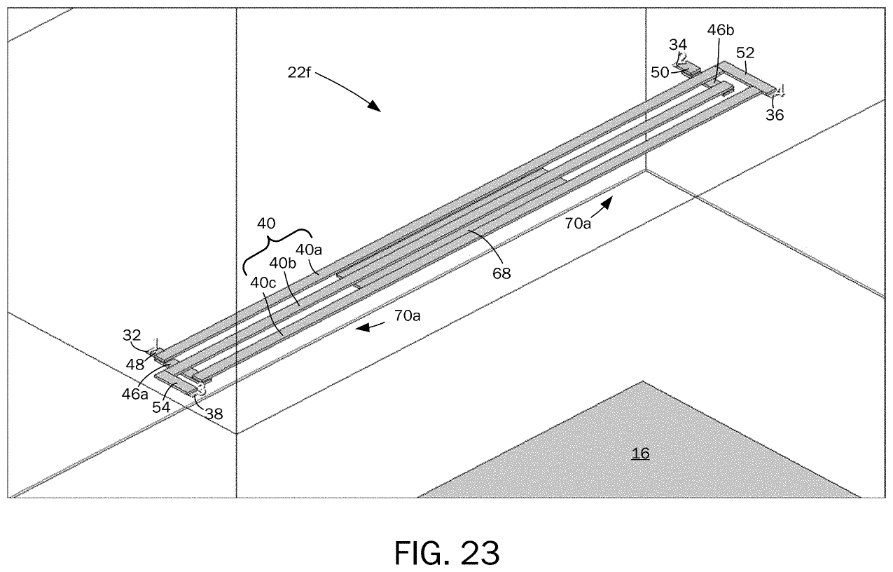

FIGS. 22 and 23 depict a sixth embodiment of a 90-degree 3 dB coupler 22f. Again, the coupler 22f includes the input port 32, the isolated port 34, the first output port 36, and the second output port 38. The input port 32 may be connected to a signal source, and like the other embodiments discussed above, this sixth embodiment of the coupler 22f splits such signal and outputs a signal attenuated by 3 dB at both the first output port and the second output port 38. The phase of the signal at the first output port may be shifted by approximately 0 degrees, while the phase of the signal at the second output port 38 is understood to be shifted by approximately 90 degrees. The sixth embodiment of the coupler 22f is contemplated for higher operating frequency applications.

The foundational components of the sixth embodiment of the coupler 22f are understood to be the same as those of the fourth embodiment 22d as well as the fifth embodiment 22e. The coupler 22f is generally defined by the plurality of conductive coupled strips 40, including the first conductive coupled strip 40a, the second conductive coupled strip 40b that is spaced apart from the first conductive coupled strip 40a, and the third conductive coupled strip 40c that is spaced apart from the second conductive coupled strip 40b. All three of the conductive coupled strips 40 are understood to extend in a parallel relationship to each other.

The coupler 22e includes two interconnect strips 46, including the first interconnect strip 46a that is connected to the first conductive coupled strip 40a and the third conductive coupled strip 40c, and the second interconnect strip 46b that is connected to the second conductive coupled strip 40b. The first interconnect strip 46a is also connected to the input port 32 over the input connector strip 48. Along these lines, the second interconnect strip 46b is connected to the isolated port 34 over the isolated port connector strip 50. The first output connector strip 52 (to which the first conductive coupled strip 40a and the third conductive coupled strip 40c are connected) is connected to the first output port 36. The second output connector strip 54, on the other hand, connects the second conductive coupled strip 40b to the second output port 38.

The sixth embodiment of the coupler 22f may also incorporate a longitudinal compensating conductive stub 68 that extend along a portion of the length of the conductive coupled strips 40. Unlike the longitudinal compensating conductive stub 68 of the fifth embodiment of the coupler 22e, however, this longitudinal compensating conductive stub 68 is shorter, with a preferred embodiment specifying a length of approximately 107.5 μm. The longitudinal compensating conductive stub 68 may be disposed centrally relative to the length of the conductive coupled strips 40. Thus, there may be opposed open areas 70a and 70b between the stub 68 and the first interconnect strip 46a, and between the stub 68 and the second interconnect strip 46b, respectively. The width of the longitudinal compensating conductive stub 68 is understood to be the same 15 μm, which may completely overlap the second conductive coupled strip 40b, and bordering the first and third conductive coupled strips 40a, 40c.

As indicated above, the spacing between the conductive coupled strips 40 may be 5 μm. The overall length of the conductive coupled strips 40 may be 287.5 μm, with an overall edge-to-edge width of 25 μm (5 μm width of the first conductive coupled strip 40a, a spacing of 5 μm between the first and second conductive coupled strips 40a, 40b, 5 μm width of the second conductive coupled strip 40b, a spacing of 5 μm between the second and third conductive coupled strips 40b, 40c, and 5 μm width of the third conductive coupled strip 40c). The overall footprint of the coupler 22f may be approximately 307.5 μm×37.5 μm.

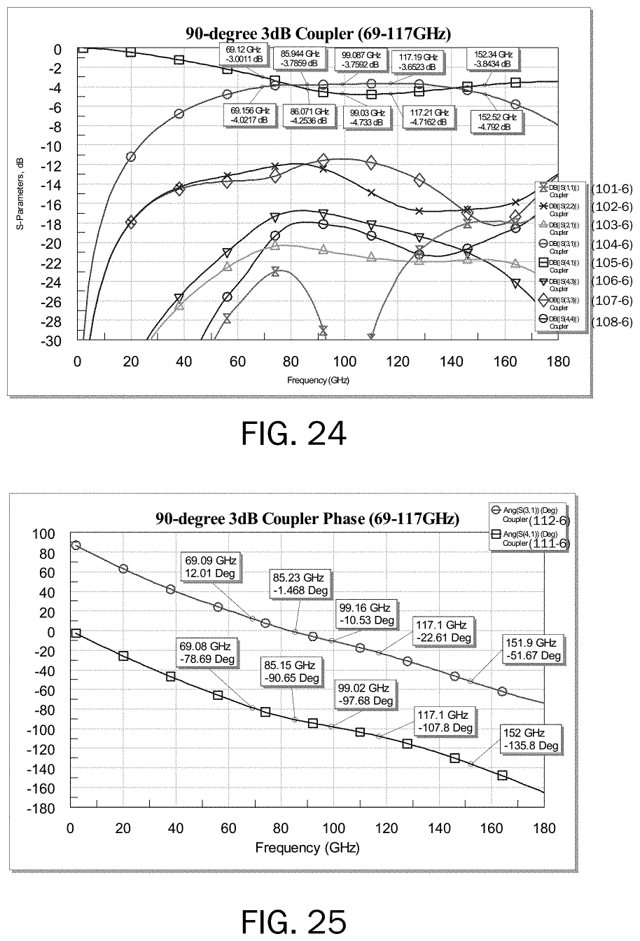

The graphs of FIGS. 24 and 25 show the simulated performance of the sixth embodiment of the coupler 22f. FIG. 24 plots the simulated scattering parameters (S-Parameters over a frequency sweep between 0 to 180 GHz, with a first plot 101-6 showing the reflection coefficient/return loss S11 at the input port 32, and a second plot 102-6 showing the reflection coefficient S22 at the isolated port 34. A third plot 103-6 shows the insertion loss S21 between the isolated port 34 and the input port 32, and a fourth plot 104-6 the shows the insertion loss S31 between the second output port 38 and the input port 32. A fifth plot 105-6 shows the insertion loss S41 between the first output port 36 and the input port 32. A sixth plot 106-6 shows the isolation between the first output port 36 and the second output port 38 (S43). A seventh plot 107-6 shows the output reflection coefficient S33 of the second output port 38, and an eighth plot 108-6 shows the output reflection coefficient S44 of the first output port 36.

The graph of FIG. 21 illustrates the simulated phase shift performance of the sixth embodiment of the coupler 22f over the same frequency sweep of 0 to 180 GHz. A 69 GHz to 117 GHz is referenced frequency range in which amplitude imbalance is below 1 dB. A first plot 111-6 shows the phase shift that gets applied to the input signal on the input port 32 when output to the first output port 36, and a second plot 112-6 shows the phase shift at the second output port 38.

The following table 6 summarizes the simulated difference in output signal power from the first output port 36 and the second output port 38, as well as the output signal phase from the same, across selected operating frequencies. The average power loss at either of the output ports 36, 38 for each of the selected operating frequencies are also presented.

TABLE 6

| | F (GHz) | | | | |
|---|---|---|---|---|---|
| | 69 | 86 | 99 | 117 | 152 |
| | GHz | GHz | GHz | GHz | GHz |
| Delta OUT, dB | 1.0 | 0.47 | 0.97 | 1.06 | 1.0 |
| Delta Angle, | 90.7 | 89.18 | 87.15 | 85.19 | 84.13 |
| degree | | | | | |
| Average Loss, | 3.51 | 4.02 | 4.25 | 4.18 | 4.32 |
| dB | | | | | |

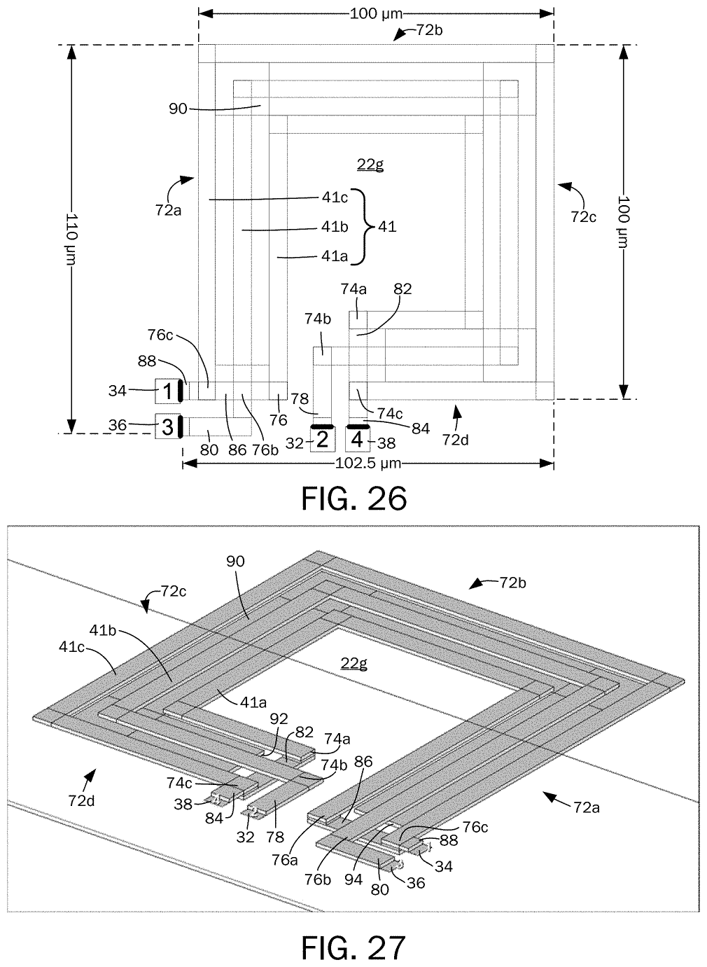

FIGS. 26 and 27 illustrate a seventh embodiment of the 90-degree 3 dB coupler 22g that has an alternative shape of the coupled strips. FIG. 26 is a top plan view, while FIG. 27 is a bottom perspective view with the coupler 22g flipped over. Like the other embodiments, however, the coupler 22g includes the input port 32, the isolated port 34, the first output port 36, and the second output port 38. The input port 32 is connectible to a signal source, and the coupler 22 is understood to split the signal to the first output port 36 and the second output port 38.

The coupler 22g is defined by a plurality of loop strips 41, of which there are three in the illustrated embodiment. In further detail, there is an inner loop strip 41a, middle loop strip 41b, and an outer loop strip 41c, each of which are defined by four sides: a left side 72a, a top side 72b, a right side 72c, and a bottom side 72d. As referenced herein, right, left, top, and bottom are used only to distinguish one side from another, rather than a strict requirement that such sides are on the right, left, top, or bottom.

Each of the loop strips 41a-41c are further defined by respective first ends 74a-74c closest to the bottom side 72d, as well as second ends 76a-76c that are closest to the left side 72a. The first end 74b of the middle loop strip 41b is connected to the input port 32 over an input connector strip 78. The second end 76b of the middle loop strip 41b is connected to the first output port 36 via a first output connector strip 80. The first end 74a of the inner loop strip 41a and the first end 74c of the outer loop strip 41c are bridged together over a first interconnect strip 82, which, in turn, is connected to the second output port 38 via a second output port connector strip 84. At the opposite end of the loop strips 41, and specifically the second end 76a of the inner loop strip 41a and the second end 76c of the outer loop strip 41c, there is a second interconnect strip 86 that bridges the two together. The second interconnect strip 86 is connected to the isolated port 34 via an isolated port connector strip 88.

In the illustrated embodiment, the coupler 22g may have overall dimensions of 110 μm×102.5 μm. The left side 72a, the outermost dimensions of which are defined by the extent of the outer loop strip 41c as well as the width of the first output connector strip 80, is understood to be 110 μm. The top side 72b is defined by the extent of the outer loop strip 41c corresponding thereto, may have a length of 100 μm. The right side 70c is likewise defined by the extent of the outer loop strip 41c corresponding thereto, and may also be 100 μm. The bottom side 72d, which includes first output connector strip 80 and the isolated port connector strip 88, is understood to extend the dimensions to 102.5 μm. Each of the loop strips 41 are understood to be 5 μm in width, and the spacing between each of the loop strips 41 may also be 5 μm.

Vertically offset from the foregoing components of the coupler 22g is a compensating conductive loop 90 that extends along the same profile as the inner loop strip 41a and centered thereon. The compensating conductive loop 90 similarly has a first end 92 that generally corresponds to the first ends 74 of the loop strips 41, as well as an opposed second end 94 that generally corresponds to the second ends 76 of the loop strips 41.

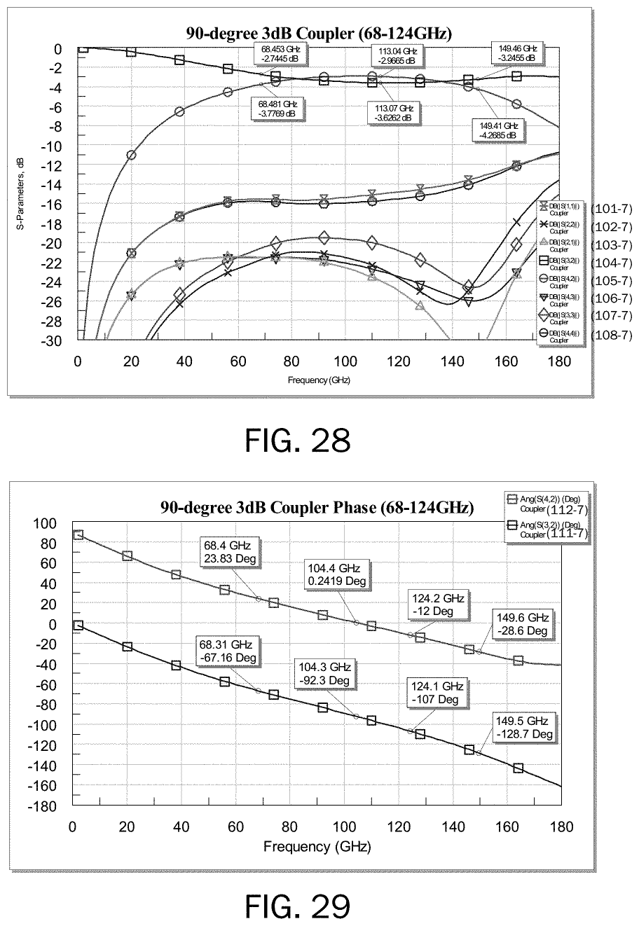

The graphs of FIGS. 28 and 29 show the simulated performance of the seventh embodiment of the coupler 22g. FIG. 28 plots the simulated scattering parameters (S-Parameters over a frequency sweep between 0 to 180 GHz, with a first plot 101-7 showing the reflection coefficient/return loss S11 at the input port 32, and a second plot 102-7 showing the reflection coefficient S22 at the isolated port 34. A third plot 103-6 shows the insertion loss S21 between the isolated port 34 and the input port 32, and a fourth plot 104-7 the shows the insertion loss S31 between the second output port 38 and the input port 32. A fifth plot 105-7 shows the insertion loss S41 between the first output port 36 and the input port 32. A sixth plot 106-7 shows the isolation between the first output port 36 and the second output port 38 (S43). A seventh plot 107-7 shows the output reflection coefficient S33 of the second output port 38, and an eighth plot 108-7 shows the output reflection coefficient S44 of the first output port 36.

The graph of FIG. 29 illustrates the simulated phase shift performance of the seventh embodiment of the coupler 22g over the same frequency sweep of 0 to 180 GHz. A first plot 111-7 shows the phase shift that gets applied to the input signal on the input port 32 when output to the first output port 36, and a second plot 112-7 shows the phase shift at the second output port 38.

The following table 7 summarizes the simulated difference in output signal power from the first output port 36 and the second output port 38, as well as the output signal phase from the same, across selected operating frequencies. The average power loss at either of the output ports 36, 38 for each of the selected operating frequencies are also presented.

TABLE 7

F (GHz)

| | 68 | 113 | 124 | 149 |
|---|---|---|---|---|
| | GHz | GHz | GHz | GHz |
| Delta OUT, dB | 1.0 | 0.66 | 0.97 | 1.0 |
| Delta Angle, | 90.99 | | 95 | 100.1 |
| degree | | | | |
| Average Loss, | 3.25 | 3.3 | | 3.76 |
| dB | | | | |

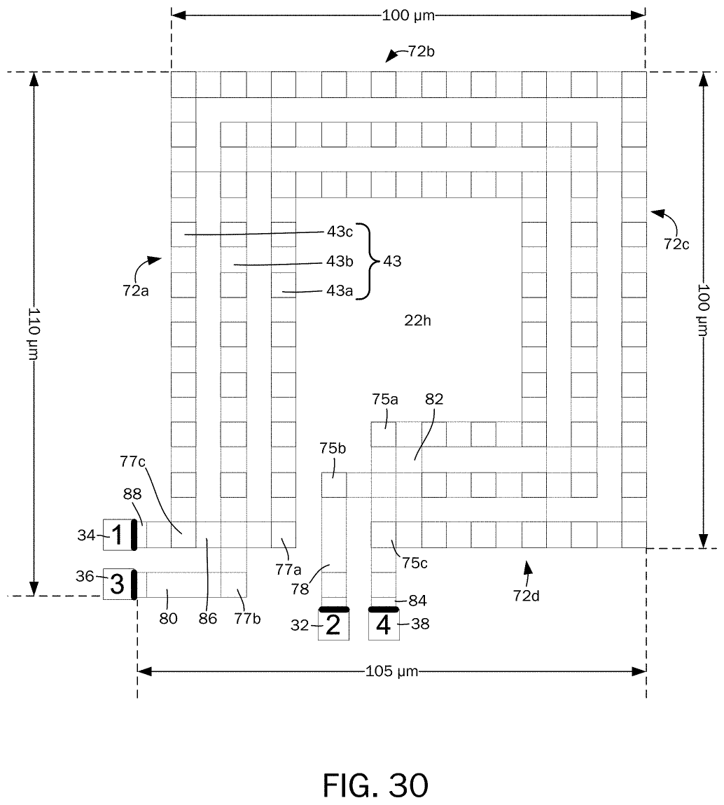

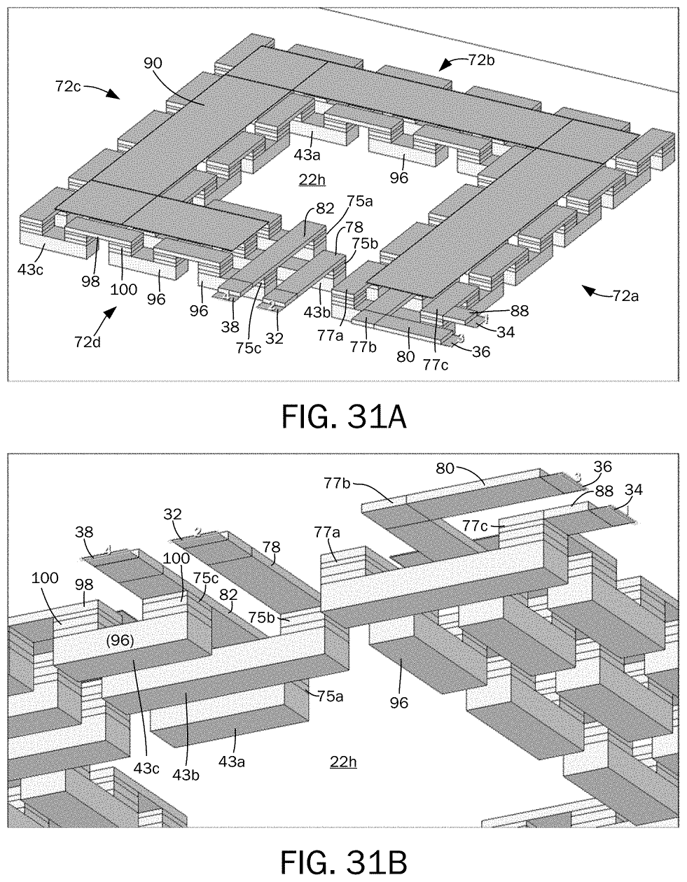

FIGS. 30, 31A, and 31B show an eighth embodiment of the 90-degree 3 dB coupler 22h, which has a similar shape/profile as the seventh embodiment 22g discussed above. As will be detailed further, the eighth embodiment 22h incorporates a meander configuration in each of the loop strips 41. FIG. 30 is a top plan view of the coupler 22h, while FIG. 31A is a bottom perspective view of the coupler 22h flipped over. The coupler 22g includes the input port 32, the isolated port 34, the first output port 36, and the second output port 38. The input port 32 is connectible to a signal source, and the coupler 22 is understood to split the signal to the first output port 36 and the second output port 38.

The coupler 22g is defined by a plurality of loop strips 43, of which there are three in the illustrated embodiment. In further detail, there is an inner loop strip 43a, middle loop strip 43b, and an outer loop strip 43c, each of which are defined by four sides: a left side 72a, a top side 72b, a right side 72c, and a bottom side 72d. Again, right, left, top, and bottom are used only to distinguish one side from another, rather than a strict requirement that such sides are on the right, left, top, or bottom.

Each of the loop strips 43a-43c are further defined by respective first ends 75a-75c closest to the bottom side 72d, as well as second ends 77a-77c that are closest to the left side 72a. The first end 75b of the middle loop strip 43b is connected to the input port 32 over the input connector strip 78. The second end 77b of the middle loop strip 43b is connected to the first output port 36 via the first output connector strip 80. The first end 75a of the inner loop strip 43a and the first end 75c of the outer loop strip 43c are bridged together over the first interconnect strip 82, which, in turn, is connected to the second output port 38 via the second output port connector strip 84. At the opposite end of the loop strips 43, and specifically the second end 77a of the inner loop strip 43a and the second end 77c of the outer loop strip 43c, the second interconnect strip 86 bridges the two together. The second interconnect strip 86 is connected to the isolated port 34 via the isolated port connector strip 88.

As indicated above, each of the loop strips 43 are understood to have a vertical meander configuration, in which different segments thereof are a part of different conductive layers and turn back and forth such that the overall length of the loop strip is shorter than an otherwise straight/flattened strip would be. In this regard, there are first segments 96 in each of the loop strips 43 that are implemented on the AP metal layer of the semiconductor die. Additionally, there may be second segments 98 in each of the loop strips 43 that are implemented on the M6 metal layer of the semiconductor die. There are corresponding areas of horizontal overlap between the first segments 96 and the second segments 98, with the layers being interconnected with vias 100. According to one embodiment, the M6 metal layer may be 1 μm thick, and the AP metal layer may be 3 μm thick.

Vertically offset from the foregoing components of the coupler 22h is the compensating conductive loop 90 that extends along the same profile as the inner loop strip 43a and centered thereon. The compensating conductive loop 90 may be implemented on the M5 metal layer, and have a thickness of 0.1 μm.

In the illustrated embodiment, the coupler 22h may have overall dimensions of 110 μm×105 μm. The left side 72a, the outermost dimensions of which are defined by the extent of the outer loop strip 43c as well as the width of the first output connector strip 80, is understood to be 110 μm. The top side 72b is defined by the extent of the outer loop strip 43c corresponding thereto, may have a length of 100 μm. The right side 70c is likewise defined by the extent of the outer loop strip 43c corresponding thereto, and may also be 100 μm. The bottom side 72d, which includes first output connector strip 80 and the isolated port connector strip 88, is understood to extend the dimensions to 105 μm. Each of the loop strips 43 are understood to be 5 μm in width, and the spacing between each of the loop strips 43 may also be 5 μm.

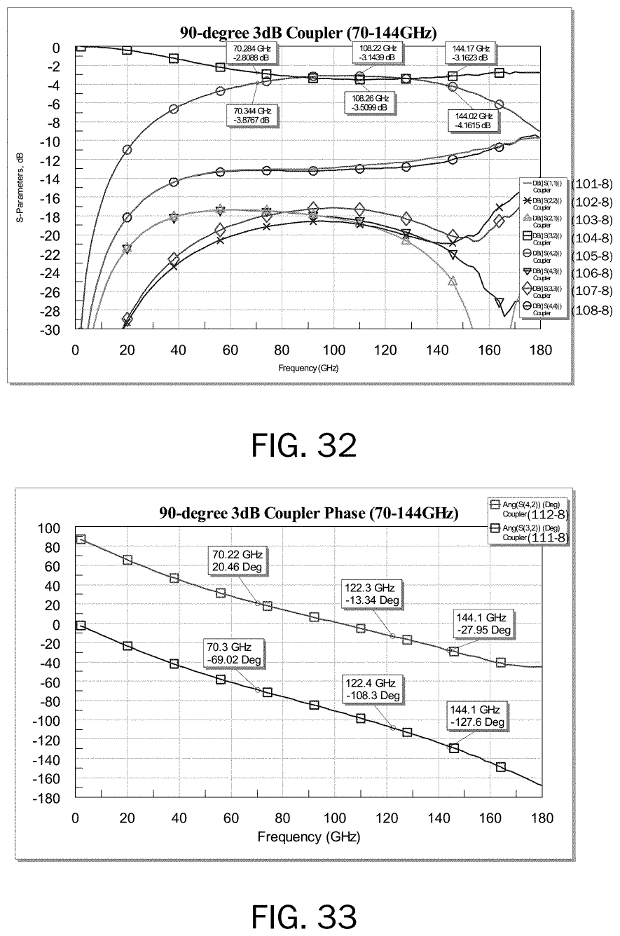

The graphs of FIGS. 32 and 33 show the simulated performance of the eighth embodiment of the coupler 22h. FIG. 32 plots the simulated scattering parameters (S-Parameters over a frequency sweep between 0 to 180 GHz, with a first plot 101-8 showing the reflection coefficient/return loss S11 at the input port 32, and a second plot 102-8 showing the reflection coefficient S22 at the isolated port 34. A third plot 103-6 shows the insertion loss S21 between the isolated port 34 and the input port 32, and a fourth plot 104-8 the shows the insertion loss S31 between the second output port 38 and the input port 32. A fifth plot 105-8 shows the insertion loss S41 between the first output port 36 and the input port 32. A sixth plot 106-8 shows the isolation between the first output port 36 and the second output port 38 (S43). A seventh plot 107-8 shows the output reflection coefficient S33 of the second output port 38, and an eighth plot 108-8 shows the output reflection coefficient S44 of the first output port 36.

The graph of FIG. 33 illustrates the simulated phase shift performance of the eighth embodiment of the coupler 22h over the same frequency sweep of 0 to 180 GHz. A first plot 111-8 shows the phase shift that gets applied to the input signal on the input port 32 when output to the first output port 36, and a second plot 112-8 shows the phase shift at the second output port 38.

The following table 8 summarizes the simulated difference in output signal power from the first output port 36 and the second output port 38, as well as the output signal phase from the same, across selected operating frequencies. The average power loss at either of the output ports 36, 38 for each of the selected operating frequencies are also presented.

TABLE 8

F (GHz)

| | 70 | 108 | 122 | 144 |
|---|---|---|---|---|
| | GHz | GHz | GHz | GHz |
| Delta OUT, dB | 1.07 | 0.37 | | 1.0 |
| Delta Angle, | 89.48 | | 94.96 | 99.35 |
| degree | | | | |
| Average Loss, | 3.34 | 3.33 | | 3.66 |
| dB | | | | |

The particulars shown herein are by way of example and for purposes of illustrative discussion of the embodiments of the present disclosure only and are presented in the cause of providing what is believed to be the most useful and readily understood description of the principles and conceptual aspects. In this regard, no attempt is made to show details with more particularity than is necessary, the description taken with the drawings making apparent to those skilled in the art how the several forms of the present disclosure may be embodied in practice.

What is claimed is:

1. A coupler with an input port, an isolated port, a first output port, and a second output port, comprising:
an input connector strip connected to the input port;
an isolated port connector strip connected to the isolated port and spaced apart from the input port;
a first output connector strip connected to the first output port;
a second output connector strip connected to the second output port and spaced apart from the first output connector strip;
a first interconnect strip connected to the input connector strip;
a second interconnect strip connected to the isolated port connector strip; and
a plurality of conductive coupled strips, a first one of the conductive coupled strips extending from the input connector strip to the second output connector strip, a second one of the conductive coupled strips extending from the first interconnect strip to the second interconnect strip, and a third one of the conductive coupled strips extending from the first interconnect strip to the second output connector strip.

2. The coupler of claim 1, wherein the first interconnect strip and the second interconnect strip are on a first metal layer, and the first output connector strip and the second output connector strip are on a second metal layer different from the first metal layer.

3. The coupler of claim 2, wherein the first metal layer is an AP layer and the second metal layer in an M7 layer on a semiconductor die.

4. The coupler of claim 3, wherein the AP layer defines a thickness of approximately 3 μm, and the M7 layer defines a thickness of approximately 1 μm.

5. The coupler of claim 1, wherein widths of the conductive coupled strips are each approximately 5 μm.

6. The coupler of claim 1, wherein spacing between adjacent pairs of the conductive coupled strips is approximately 5 μm.

7. The coupler of claim 1, wherein lengths of the conductive coupled strips are each approximately 750 μm.

8. The coupler of claim 2, further comprising floating conductive patches on adjacent to and spaced apart from outer ones of the plurality of conductive coupled strips.

9. The coupler of claim 8, wherein the floating conductive patches are on the first metal layer.

10. The coupler of claim 8, wherein the floating conductive patches have a width of approximately 75 μm.

11. The coupler of claim 8, wherein a first one of the floating conductive patches extends between the input connector strip and the isolated port connector strip, and a second one of the floating conductive patches extends between the first output connector strip and the second output connector strip.

12. The coupler of claim 8, further comprising:
an elongate conductive strip at least partially overlapping a central one of the plurality of conductive coupled strips, the elongate conductive strip being disposed on the second metal layer.

13. The coupler of claim 12, wherein the elongate conductive strip has a width of approximately 10 μm.

14. The coupler of claim 1, further comprising:
a set of compensation stubs spaced along a length of the conductive coupled strips, each of the compensation strips being oriented crosswise to the conductive coupled strips.

15. The coupler of claim 14, wherein the compensation stubs are disposed on a third metal layer.

16. The coupler of claim 15, wherein the first metal layer is an M6 layer on a semiconductor die, the second metal layer is an M7 layer on the semiconductor die, and the third metal layer is an AP layer on the semiconductor die.

17. The coupler of claim 1, further comprising:
a longitudinal compensation stub positioned in alignment with the conductive coupled strips.

18. The coupler of claim 17, wherein the longitudinal compensation stub extends at least across a space between the first interconnect strip and the second interconnect strip.

19. The coupler of claim 17, wherein the longitudinal compensation stub extends only partially across a space between the first interconnect strip and the second interconnect strip.

20. The coupler of claim 17, wherein the compensation stubs are disposed on a third metal layer.

21. The coupler of claim 19, wherein the first metal layer is an M6 layer on a semiconductor die, the second metal layer is an M7 layer on the semiconductor die, and the third metal layer is an AP layer on the semiconductor die.

22. A coupler with an input port, an isolated port, a first output port, and a second output port, comprising:
a middle loop strip connected to the input port and the first output port;
an inner loop strip connected to the second output port and the isolated port and spaced apart from the middle loop strip;
an outer loop strip connected to the second output port and the isolated port and spaced apart from the middle loop strip;
a first interconnect strip bridging a first end of the inner loop strip to a first end of the outer loop strip and connected to the second output port;
a second interconnect strip bridging a second end of the inner loop strip to a second end of the outer loop strip and connected to the isolated port; and
one or more compensating conductive stubs, the middle loop strip being in an at least partially overlapping relationship with each of the one or more compensating conductive stubs.

23. The coupler of claim 22, wherein the middle loop strip, the inner loop strip, and the outer loop strip are each defined by a plurality of segments of variable thickness, at least some of the segments spanning multiple semiconductor metal layers.

24. The coupler of claim 23, wherein one of the segments of a given one of the middle loop strip, the outer loop strip, and the inner loop strip is on an AP metal layer of a semiconductor die.

25. The coupler of claim 23, wherein one of the segments of a given one of the middle loop strip, the outer loop strip, and the inner loop strip is on an M6 metal layer of a semiconductor die.

26. The coupler of claim 23, wherein the one or more compensating conductive subs is on an M5 metal layer of a semiconductor die.

27. The coupler of claim 23, wherein a first one of the segments of a given one of the middle loop strip, the outer loop strip, and the inner loop strip is on an AP metal layer of a semiconductor die, and a second one of the segments the given one of the middle loop strip, the outer loop strip, and the inner loop strip is on an M6 metal layer of the semiconductor die, a portion of the first segment at least partially overlapping a portion of the second segment, with a via vertically connecting the portion of the first segment and the portion of the second segment.
